(19) United States
(12) Patent Application Publication
(10) Pub. No.: US 2024/0367081 A1
(43) Pub. Date: Nov. 7, 2024

(54) AIR INLET OR AIR OUTLET FILTER FOR A SWITCH CABINET HOUSING AND A CORRESPONDING SWITCH CABINET ARRANGEMENT

(71) Applicant: RITTAL GMBH & CO. KG, Herborn (DE)

(72) Inventor: Markus WEBER, Waldbrunn (DE)

(21) Appl. No.: 18/683,964

(22) PCT Filed: Aug. 1, 2022
(86) PCT No.: PCT/DE2022/100552

§ 371 Date: Feb. 15, 2024

(30) Foreign Application Priority Data
Sep. 3, 2021 (DE) 10 2021 122 887.5

(51) Int. Cl. B01D 46/00; B01D 46/10; B01D 46/52; H02B 1/30

(52) U.S. Cl. CPC B01D 46/0036; B01D 46/10; B01D 46/521; H02B 1/306; B01D 2273/30; B01D 2275/10; B01D 2279/45

(57) ABSTRACT

An air inlet or air outlet filter for a switch cabinet housing, having a filter housing in which a filter substrate is arranged with a pleated filter which completely covers an air passage cross-section of the filter housing, wherein the filter substrate has a liquid-absorbing absorber mat made of nonwoven fabric. A corresponding switch cabinet arrangement is thus described.

### CROSS-REFERENCE TO RELATED APPLICATIONS

This application is a U.S. National Phase Application under 35 U.S.C. 371 of International Application No. PCT/DE2022/100552, filed on Aug. 1, 2022, which claims the benefit of German Patent Application No. 10 2021 122 887.5, filed on Sep. 3, 2021. The entire disclosures of the above applications are incorporated herein by reference.

### BACKGROUND

This section provides background information related to the present disclosure which is not necessarily prior art.

### Technical Field

The invention is based on an air inlet or air outlet filter for a switch cabinet housing, having a filter housing in which a filter substrate is arranged with a pleated filter which completely covers an air passage cross-section of the filter housing. Such an air inlet or air outlet filter is known from EP 1 909 548 B1. A similar fan filter is thus described in DE 201 07 242 U1. A filter unit for a switch cabinet is known from DE 10 2010 016 504 A1 and superabsorbent-containing textiles are known from WO 2011/054784 A1.

### Discussion

The air inlet or air outlet filters known from the prior art have the disadvantage that they represent a weak point with respect to the achievable IP protection class of a switch cabinet housing in which they are installed, since the air inlet or air outlet filters naturally thus have a certain permeability to liquid because of their air permeability if the air inlet or air outlet filter is acted on for a relatively long time or with a considerable liquid volume flow.

### SUMMARY

This section provides a general summary of the disclosure and is not a comprehensive disclosure of its full scope or all of its features.

It is therefore one aspect of the invention to propose an air inlet or air outlet filter of the type described at the beginning which has the lowest possible permeability to liquids.

Accordingly, in an air inlet or air outlet filter of the type described at the beginning, it is provided that the filter substrate has an absorber mat made of nonwoven fabric. The nonwoven fabric can have absorbing properties with respect to liquid, preferably water, and/or a superabsorbent, wherein the superabsorbent can be accommodated in the nonwoven fabric or the nonwoven fabric can be coated with the superabsorbent.

The pleated filter can comprise the nonwoven fabric, consequently pleated filter and absorber mat can be formed in one piece or be the same component. The nonwoven fabric can also be provided in addition to the pleated filter and cover the air passage cross-section of the filter housing.

The nonwoven fabric can be liquid-absorbing and/or hydrophobic. The nonwoven fabric preferably consists of thermally and/or mechanically bonded polyester fibres. The fibres of the nonwoven fabric can be hydrophobic, while the nonwoven formed from the hydrophobic fibres can have water-absorbing properties.

At least in the case that the nonwoven fabric is hydrophobic, the nonwoven fabric and/or the pleated filter can have on a lower side a liquid-absorbing material strip, preferably a hydrophilic nonwoven fabric. Due to the hydrophobic properties of the nonwoven fabric, water running off the nonwoven fabric in the vertical direction can be absorbed in the liquid-absorbing material strip.

The liquid-absorbing material strip can be arranged outside the air passage cross-section of the filter housing. The liquid volume absorbed by the material strip is thus kept outside the cross-section and thus an additional protection against the accidental penetration of the liquid into the switch cabinet housing is provided.

The nonwoven fabric of the absorber mat can have a weight per unit area of less than 250 g/m2, preferably of less than 200 g/m2 and particularly preferably of less than 180 g/m2. As a result, the pressure loss of the absorber mat can be reduced to an insignificant extent. The absorber mat made of nonwoven fabric can be arranged downstream of the pleated filter in the flow direction in the case of an air inlet filter and upstream of the pleated filter in the flow direction in the case of an air outlet filter. The absorber mat made of nonwoven fabric can be arranged adjacent to the pleated filter or at a distance from the pleated filter.

When a superabsorbent is used, it has the property that it (greatly) increases its volume when exposed to liquid and thus reduces the permeability of the filter substrate to any fluid. Depending on the concentration of the superabsorbent contained in the filter substrate, it is even conceivable that the superabsorbent in the swollen state (hydrogel) completely blocks the filter substrate and thus makes the air inlet or air outlet filter virtually impermeable to air at the usual pressure differences (for example of a filter fan).

The filter substrate can be penetrated by the superabsorbent or coated with it. If the filter substrate is a nonwoven, a granularly provided superabsorbent can be held by the fibers of the nonwoven material. A binding agent can be provided in order to hold the superabsorbent on the nonwoven material. The superabsorbent is preferably not provided in or on the pleated filter. Instead, the filter substrate can have an additional nonwoven which is coated with the superabsorbent or in which the superabsorbent is received. The nonwoven can be provided as a separate component of the filter substrate independently of the pleated filter or in combination with the pleated filter.

The pleated filter can have the nonwoven of the liquid-absorbing mat or the nonwoven of the liquid-absorbing mat can be provided in addition to the pleated filter as a nonwoven covering the air passage cross-section of the filter housing. The superabsorbent can be received in the nonwoven. Alternatively, the nonwoven can be coated with the superabsorbent. It is also conceivable that the nonwoven is both penetrated by the superabsorbent and coated with the superabsorbent. Independently of the nonwoven having the superabsorbent, the pleated filter can also consist of a nonwoven, therefore a commercially available pleated filter for use in air inlet or air outlet filters, for example of a filter fan.

The nonwoven can be coated and/or penetrated with the superabsorbent as granules, wherein the granules are held on the fibers by fibers of the nonwoven or by a binding agent.

In order to avoid that, when the air inlet or air outlet filter is acted upon with a liquid, the filter substrate is completely blocked on account of the swelling superabsorbent and therefore in particular also the fresh air required for cooling the components received in the switch cabinet housing can no longer be transported into the switch cabinet interior, it is provided in a particular embodiment of the invention that the nonwoven has the superabsorbent only within a proportion of the air passage cross section of the filter housing, wherein the proportion is preferably less than 50% of the air passage cross section. The proportion with the superabsorbent can be provided in particular in a lower region of the nonwoven. Rain water running off, for example, can accumulate there on a lamellar grid covering the filter substrate. Such that the air inlet or air outlet filter is particularly susceptible at this point to the entry of liquid into the switch cabinet interior, which is entrained, for example, by an air flow which is generated by a fan of an air inlet filter, therefore by a filter fan.

The superabsorbent can thus be arranged exclusively in a lower region of the nonwoven in the installation position of the air inlet or air outlet filter on a switch cabinet housing. In particular, an upper region of the nonwoven with respect to the lower region can be free of the superabsorbent.

The superabsorbent can be provided in a crystalline state in the nonwoven or on the nonwoven, wherein the superabsorbent in a swollen state as hydrogel has a volume which is at least 40 times, preferably at least 70 times and particularly preferably at least 100 times greater than the volume in the crystalline state.

The nonwoven can have a sandwich structure, with a first and a second outer filter nonwoven, between which an absorber layer having the superabsorbent is arranged. In this embodiment, in particular the two outer filter nonwovens can be free of superabsorbent. The absorber layer can be a further filter nonwoven which is independent of the filter substrate and has the superabsorbent.

The filter substrate preferably has the pleated filter and the absorber mat as separate components which, for example, can be laid one on top of the other into the housing of the air inlet or air outlet filter. This filter substrate is also suitable in particular for air inlet filters formed as filter fans with a horizontal or vertical lamellar grid. The pleated filter here serves for filtration and can contribute to increasing the volume flow of the filter fan with its larger surface area in comparison with conventional nonwoven filters. Here, protection types of IP55 can hitherto be implemented either only with a complex, mechanical labyrinth seal or with two closely meshed nonwoven filters lying one behind the other. The absorber mat, on the other hand, serves as a water separator and ensures that, in particular in the case of filter fans, no water reaches the switch cabinet when the fan motor is running/sucking.

If the filter substrate has the pleated filter and the absorber mat as separate components, these can be arranged at a distance from one another. As a result, the transfer of the liquid passing through the pleated filter to the absorber mat is reduced and the latter is thus subjected to less great loading. This positive effect can be intensified further by the fact that the pleated filter and the absorber mat are not arranged parallel, i.e. at an acute angle, to one another. In this case, the pleated filter is preferably oriented parallel to the air passage cross-section and the absorber mat is angled with respect thereto, for example by 5 to 15°.

According to another aspect, a switch cabinet arrangement having a switch cabinet housing and at least one air inlet or air outlet filter of the type described above is described. In the case of the at least one air inlet or air outlet filter, the filter housing can be mounted in a vertical housing wall of the switch cabinet housing and have a lamellar grid on an outer side of the switch cabinet housing.

The lamellar grid can have a multiplicity of vertically extending lamellae or consist of a multiplicity of lamellae extending vertically and parallel to one another.

The filter housing can have a filter housing cover which has the lamellar grid and can be pivoted with respect to a filter housing lower part fixed in the housing wall or can be removed therefrom. The filter substrate can be received between the filter housing lower part and the filter housing cover. In order to facilitate the replacement of the filter substrate, the filter substrate can be held in a receptacle of the filter housing cover. In one embodiment, the pleated filter of the filter substrate is held in the filter housing cover, while a nonwoven with the superabsorbent received therein or coated thereon is held in the filter housing lower part.

In the case of a multi-part filter substrate consisting of a pleated filter and a separate nonwoven having the superabsorbent, in order to avoid blockage of the filter substrate by the particles filtered out of the ambient air, only the pleated filter can be replaced in the case of a rotation of the filter substrate, since the nonwoven is subject to no or only substantially less wear in comparison with the pleated filter. Multi-part filter substrates are therefore particularly resource-saving.

The filter housing can have a filter housing cover which has the lamellar grid and can be pivoted with respect to a filter housing lower part or can be removed therefrom and in which the pleated filter with the nonwoven and the superabsorbent received therein is held.

The pleated filter can be arranged in the interior of the filter housing so as to face the lamellar grid, wherein the lamellae extend parallel to the pleats of the pleated filter, with the result that a vertically running channel which is open toward the lamellar grid is formed in each case between adjacent pleats of the pleated filter and promotes the discharge of liquid which is applied to the air inlet or air outlet filter.

In one embodiment, the switch cabinet arrangement can have an air inlet filter and an air outlet filter of the type described above, wherein the air inlet filter is formed as a filter fan. The basic construction of a filter fan is described in DE 10 2010 016 504 A1.

A method for operating a switch cabinet arrangement of the type described above can comprise drawing in ambient air through the air inlet filter into the switch cabinet housing, conducting the ambient air through the switch cabinet housing and blowing out the ambient air through the air outlet filter. The method furthermore comprises applying liquid, preferably rain or spray water, to the air inlet and/or the air outlet filter.

When the liquid penetrates into the air inlet and/or the air outlet filter and comes into contact there with a superabsorbent, the superabsorbent swells and is converted into a hydrogel, whereupon the superabsorbent reduces the air passage cross-section of the filter housing of the relevant air inlet and/or air outlet filter or completely blocks the air passage cross-section of the filter housing. If the absorber mat does not have a superabsorbent, the liquid can be stored in the absorber mat and/or can be conducted away therefrom at a lower horizontal edge, for example drip off. Alternatively, the liquid can be stored in a liquid-absorbing nonwoven strip on the fold filter underside. In one embodiment, the liquid-absorbing nonwoven strip can have a superabsorbent.

The absorber mat can also have water-absorbing properties without the use of absorbing additives such as superabsorbents. For this purpose, the material of the nonwoven fabric, in particular the fibers, for example polyester fibers, can be formed in a highly hydrophobic manner and/or have an absorbing property. If liquid is applied to the air inlet and/or the air outlet filter, the liquid can impinge on the pleated filter which is preferably inserted vertically. As a result of this arrangement, the regions between the folds can form a vertical guide channel to an outlet from the filter fan.

If a jet with sufficiently high energy now impinges on the pleated filter, drops can pass through the pleated filter to the inside of the switch cabinet. The optional hydrophobic effect of the absorber mat now comes into play. The drops bead off from the surface and run off downwards, where they can run off to the outside under the pleated filter. The pleat filter underside can have a liquid-absorbing nonwoven strip. It can happen that individual regions of the pleated filter are saturated with water to such an extent that droplets are drawn in the direction of the inside of the cabinet by the suction effect of an optional fan of the air inlet and/or air outlet filter.

The absorber effect of the absorber mat can now come into play. The droplets can be bound in the fibers of the absorber mat and do not reach the switch cabinet even when the fan is running. As a result of the absorption, the volume flow is temporarily reduced by closure of individual partial regions of the active filter surface and thus additionally contributes positively to the existence of an IP protection class requirement. In the absence of absorber substances such as superabsorbents, the absorber mat can simply be knocked out and can be used again immediately. Alternatively, the absorber mat can be reused after evaporation of the absorbed water in the air inlet and/or air outlet filter. The resulting evaporation cold can compensate for the sometimes temporarily reduced air volume flow due to the liquid absorption. This embodiment is thus also reversible in comparison with the solutions known from the prior art.

Filter substrates known from the prior art with at least two layers of nonwoven filters have the disadvantage of generating a high differential pressure, such that the main function of the air inlet and/or air outlet filter, the cooling with ambient air, is greatly reduced. After the water has entered, the nonwoven filters are saturated with liquid such that this liquid can enter the cabinet. The filter substrates must therefore necessarily be replaced. In addition, due to the closely meshed fibers, these filter combinations become clogged more quickly with dust, as a result of which short maintenance intervals are necessary.

The pleated filter is preferably inserted vertically into the filter housing. Tabs can be arranged on the sides, which on the one hand facilitate the insertion into the filter housing and on the other hand assume the function of a lateral seal. The pleated filter can in each case have a nonwoven strip on an upper or lower longitudinal edge. This on the one hand has a sealing effect with respect to the filter housing and makes it possible for the liquid to run off in the lower region of the filter housing.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

Further details of the invention are explained with reference to the following figures. In the figures:

FIG. 1 shows an exemplary embodiment of an air inlet or air outlet filter according to the prior art;

FIG. 2 shows a detailed view of a filter housing in the unfolded state according to one embodiment of the invention;

FIG. 3 shows a schematic plan view of a filter substrate according to one embodiment of the invention;

FIG. 4 shows a cross-sectional view of a nonwoven according to one embodiment of the invention;

FIG. 5 shows a detailed view of a switch cabinet arrangement according to one embodiment of the invention; and

FIG. 6 shows two embodiments of a multi-part filter substrate.

### DETAILED DESCRIPTION

Example embodiments will now be described more fully with reference to the accompanying drawings.

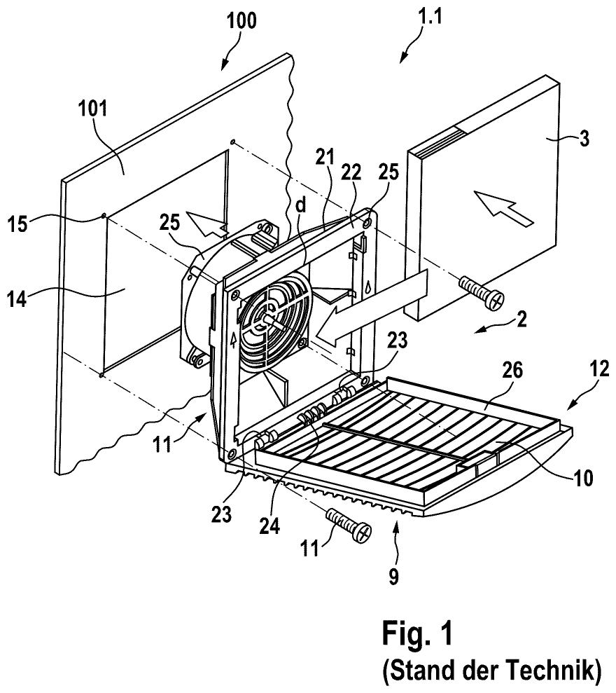

FIG. 1 shows an exemplary air inlet filter 1.1 according to the prior art. The air inlet filter 1.1 is inserted into a wall element which is formed in the present case as a vertical housing wall 101. The vertical housing wall 101 can be, for example, a side wall, a rear wall or a front door of the switch cabinet housing 100. The housing wall 101 has a square aperture 14 with which screw receptacles 15 are associated in the corner regions. The air inlet filter 1.1 can be inserted into the aperture 14. In the present case, the air inlet filter 1.1 has a filter housing 2 which, with a housing wall 21 of the filter housing lower part 11, encloses an air guiding region and defines the air passage cross-section d of the filter housing 2. A fan 25 is flange-mounted on the base of the filter housing lower part 11. The fan 25 has an electric motor and a fan which is designed to suck in ambient air and to blow it into the switch cabinet interior 1, as is symbolized by the arrow illustration in FIG. 1. Facing away from the fan 25, a circumferential collar 22 is integrally formed on the housing wall 21. The insertion movement of the filter housing 2 into the aperture 14 can be limited by means of the collar 22. In this case, the collar 22 then rests on the housing wall 101 on the front side around the aperture 14. The collar 22 has screw receptacles 15 in its corner regions. Fastening screws 16 can be guided through the latter and screwed into the screw receptacles 15 of the housing wall 101. In this way, the filter housing 2 is fixedly connected to the housing wall 101.

As can further be seen in FIG. 1, the filter housing 2 has, in addition to the filter housing lower part 11, a filter housing cover 12 which is formed substantially as an air passage grid. In this case, the air passage grid is coupled via two hinges 23 at its lower horizontal edge to the lower horizontal edge of the filter housing lower part 11. The hinges 23 form a horizontal hinge axis about which the air passage grid or the filter housing cover 12 can be adjusted between a vertical mounting position and a folded-down maintenance position illustrated in FIG. 1.

The filter housing cover 12 has three walls which merge into one another and form a filter holder 26 for the filter substrate 3. The filter substrate 3 can be laid into the filter holder 26. In this case, the filter substrate 3 is supported with its front side on lamellae 10 of the passage grid. The lamellae 10 form air inlet openings through which ambient air can be conveyed through the filter substrate 3 into the filter housing 2 and the fan 25 into the switch cabinet housing 100.

In the case of the air inlet filters known from the prior art and corresponding air outlet filters (not illustrated), the filter substrates are often formed as filter mats composed of a nonwoven material or as pleated filters composed of nonwoven material.

The known air inlet filters 1.1 and corresponding air outlet filters (not illustrated) accordingly have the disadvantage that, when the lamella grid 9 of the filter housing cover 12 is exposed to liquid, the filter mat 3 is sucked up with liquid and the liquid is optionally sucked into the switch cabinet interior at least in the case of an air inlet filter 1.1 due to the negative pressure provided by the fan 25, where the entry of liquid is already undesired due to the moisture-sensitive electrical components sometimes contained in the switch cabinet interior. Accordingly, air inlet filters and corresponding air outlet filters are the essential weak point in achieving high IP protection classes in switchgear assembly.

Accordingly, it is provided in an air inlet filter according to the invention that the filter substrate 3 received in the filter housing furthermore has an absorber mat made of a nonwoven in addition to a pleated filter.

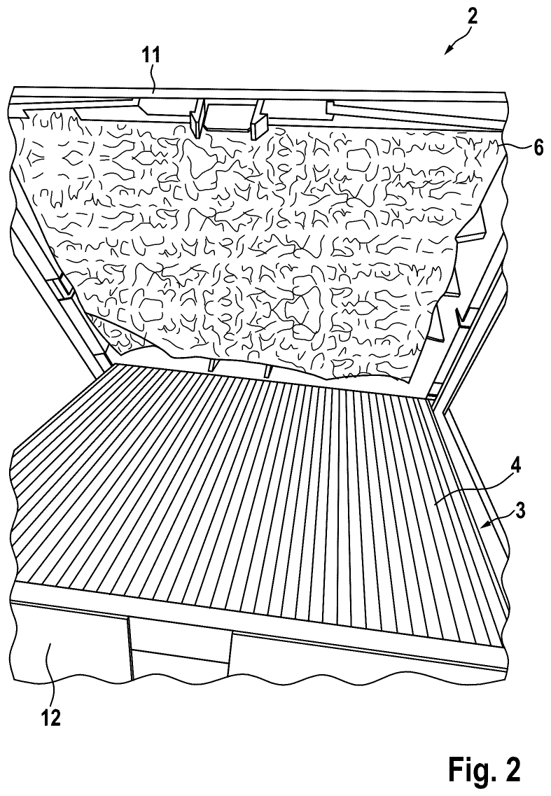

FIG. 2 shows an exemplary embodiment of such a filter housing 2, wherein the filter substrate 3 is formed in a multi-part manner, with a pleated filter 4 which is received in the filter housing cover 12 analogously to the embodiment from the prior art according to FIG. 1, and an additional nonwoven 6 which forms the absorber mat which is received in the filter housing lower part 11 and can optionally have a superabsorbent. In the folded state, i.e. when the filter housing cover 12 bears against the filter housing lower part 11 and the indicated latching connection is fixed to the filter housing lower part 11, the pleated filter 4 and the nonwoven 6 extend substantially parallel to one another, wherein the pleated filter 4 and the nonwoven 6 can be formed directly one on top of the other and adjoining one another. Alternatively, they can also be spaced apart from one another in order to prevent the transfer of liquid from the pleated filter to the nonwoven 6 of the absorber mat and thus reduce the loading of the absorber mat with liquid, such that the latter remains permeable to air for a longer time and thus the air inlet or air outlet filter can continue to maintain its original function.

Accordingly, when liquid acts on the lamellar grid (not illustrated) of the filter housing cover 12, liquid passes through the pleated filter 4 (which, due to its pleated geometry, already has a better liquid discharge than conventional filter mats), the liquid impinges on the nonwoven 6 of the absorber mat. If the absorber mat has a superabsorbent, the latter can also absorb the liquid and, due to its increase in volume, block the nonwoven 6, such that additional liquid, which may no longer be absorbed by the absorber mat, can no longer pass through the nonwoven 6 into the inside of the switch cabinet.

The nonwoven 6 can be coated with the optional superabsorbent or impregnated by the superabsorbent. The superabsorbent can be provided as granules which have a grain size which is matched to the nonwoven 6 to the extent that the fibers can hold the superabsorbent without an additional binding agent or an adhesion promoter being required. However, the superabsorbent can also be coated with an adhesion promoter on the nonwoven 6 or anchored in the nonwoven 6.

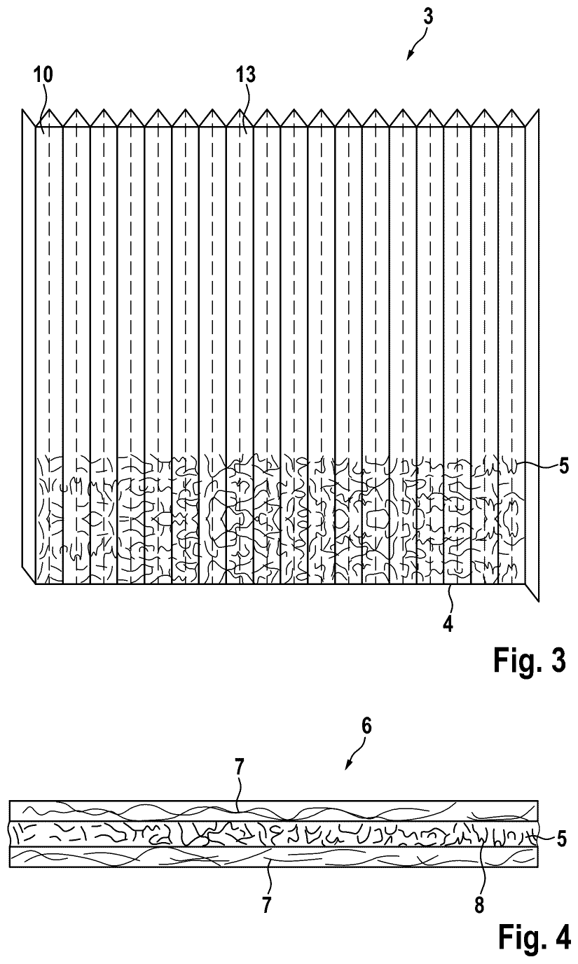

FIG. 3 shows an embodiment of a filter substrate 3, in which the pleated filter 4 has the superabsorbent 5 only in a lower region in the vertical direction, while a region located thereabove is free of the superabsorbent 5. In particular, the superabsorbent 5 can be provided only in a lower third or in a lower quarter of the filter substrate 3. Analogously to the embodiment according to FIG. 2, the superabsorbent 5 can be provided in the form of an additional nonwoven 6. Alternatively, the superabsorbent 5 can also be applied directly to the pleated filter 4, for example coated thereon or impregnated by it.

The lamellae 10 of the lamellar grid (not illustrated) of the filter housing cover are likewise indicated. As can be seen, the lamellae 10, deviating from the air inlet filters and air outlet filters known from the prior art, are also oriented vertically and parallel to the folds of the pleated filter 4. In this way, the parallel folds of the pleated filter form vertical channels 13 which can be used for discharging liquid. This comes into play in particular when the pleated filter 4 is at least partially blocked due to liquid action already taking place and liquid occurring directly at the pleated filter has to be channeled because it can no longer pass through the pleated filter.

FIG. 4 shows a further embodiment of a multilayer nonwoven 6 consisting of two outer filter nonwovens 6 which are free of superabsorbent and an absorber layer which is arranged between them and has the superabsorbent 5.

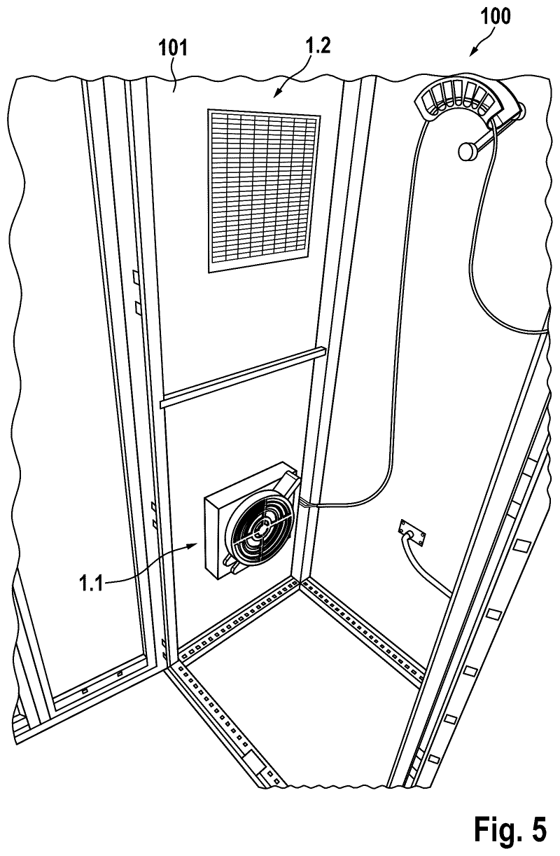

FIG. 5 shows a switch cabinet housing 100 in which an air inlet filter 1. 1 and an air outlet filter 1.2 are arranged vertically one above the other in a side wall 101. When the switch cabinet door is closed, the air volume received in the switch cabinet interior is fluidically connected substantially exclusively via the two air inlet and air outlet filters 1.1, 1.2 to the surroundings of the switch cabinet housing 100. Accordingly, ambient air can be drawn in through the air inlet filter 1.1 into the switch cabinet housing 100 via the air inlet filter 1.1 formed as a filter fan. The drawn-in ambient air can be conducted through the switch cabinet housing 100 and blown out through the air outlet filter 1.2 back into the surroundings of the switch cabinet housing 100. When liquid, for example rain or spray water, is applied to the air inlet and/or the air outlet filter 1.1, 1.2, the liquid can penetrate into the air inlet filter 1.1 and/or the air outlet filter 1.2 and come into contact with the superabsorbent of the filter substrate, whereupon the superabsorbent 5 swells and is converted into a hydrogel. The superabsorbent can thereupon reduce or completely block the air passage cross-section of the filter housing of the relevant air inlet and/or air outlet filter, such that the entry of liquid into the switch cabinet housing is prevented or at least significantly reduced.

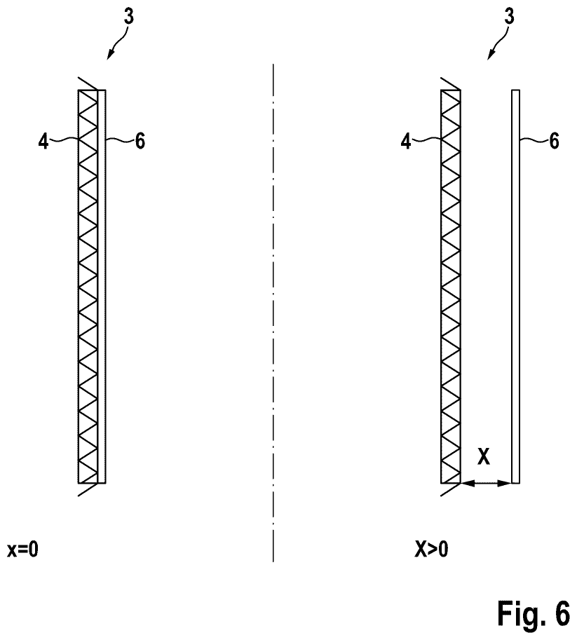

FIG. 6 shows two embodiments of a multi-part filter substrate 3 with a pleated filter 4 and a separate absorber mat in the form of a nonwoven 6. In the first embodiment (left), the absorber mat rests directly on the pleated filter 4. The absorber mat is preferably arranged behind the pleated filter 4 in the air flow direction through the filter substrate 3.

In comparison with this, in the second embodiment (right), the absorber mat is arranged at a distance x from the pleated filter 4. Analogously to the first embodiment, the absorber mat is arranged behind the pleated filter 4 in the air flow direction through the filter substrate 3. The objection has the advantage that the transfer of liquid from the pleated filter 4 to the absorber mat is made more difficult, as a result of which the liquid loading of the nonwoven 6 is reduced. As a result, the service life of the absorber mat can be increased.

As illustrated, the absorber mat is preferably arranged at a distance parallel to the pleated filter 4. In one embodiment, however, the absorber mat can also be arranged at an angle, preferably an acute angle, to the pleated filter 4. In this case, the pleated filter 4 is preferably oriented vertically and the absorber mat is tilted with respect thereto from the vertical, for example by 5° to 15°. This tilting of the absorber mat has the advantage that the absorber mat can be installed with a larger area in the filter housing and therefore the flow speed through the absorber mat is reduced, as a result of which the entry of liquid into the switch cabinet interior is made more difficult in the case of saturation of the absorber mat. In particular in the case of hydrophobic absorber mats, for example made of hydrophobic polyester fibers, in the case of an angled absorber mat the liquid stored in the absorber mat can drip off better vertically.

The features of the invention disclosed in the above description, in the drawing and in the claims can be essential both individually and in any desired combination for the realization of the invention.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-20. (canceled)

21. An air inlet or air outlet filter for a switch cabinet housing, comprsing a filter housing in which a filter substrate is arranged with a pleated filter which completely covers an air passage cross-section of the filter housing, wherein the filter substrate has a liquid-absorbing absorber mat made of nonwoven fabric, wherein the nonwoven fabric is liquid-absorbing, wherein the nonwoven fabric preferably consists of thermally and/or mechanically bonded polyester fibres, wherein the nonwoven fabric and/or the pleated filter has on a lower side a liquid-absorbing material strip, preferably a hydrophilic nonwoven fabric, wherein the liquid-absorbing material strip is arranged outside the air passage cross-section of the filter housing.

22. The air inlet or air outlet filter according to claim 21, in which the nonwoven fabric has a superabsorbent, wherein the superabsorbent is accommodated in the nonwoven fabric or the nonwoven fabric is coated with the superabsorbent.

23. The air inlet or air outlet filter according to claim 21, in which the pleated filter has the nonwoven fabric or the nonwoven fabric is provided in addition to the pleated filter covering the air passage cross-section of the filter housing.

24. The air inlet or air outlet filter according to claim 22, in which the nonwoven fabric is coated and/or interspersed with the superabsorbent as granules, wherein the granules are held on the fibers by fibers of the nonwoven fabric or by a binder.

25. The air inlet or air outlet filter according to claim 22, in which the nonwoven fabric has the superabsorbent only within a proportion of the air passage cross-section of the filter housing, wherein the proportion is preferably less than 50% of the air passage cross-section.

26. The air inlet or air outlet filter according to claim 22, in which the superabsorbent is arranged exclusively in a lower region of the nonwoven fabric in the installation position of the air inlet or air outlet filter on a switch cabinet housing, while an upper region of the nonwoven fabric with respect to the lower region is free of the superabsorbent.

27. The air inlet or air outlet filter according to claim 22, in which the superabsorbent is provided in or on the nonwoven fabric in a crystalline state and has a volume in a swollen state as hydrogel which is at least 40 times, preferably at least 70 times and particularly preferably at least 100 times greater than in the crystalline state.

28. The air inlet or air outlet filter according to claim 22, in which the nonwoven fabric has a sandwich structure, with a first and a second outer filter nonwoven, between which an absorber layer having the superabsorbent is arranged.

29. The air inlet or air outlet filter according to claim 27, in which the absorber layer is a further filter nonwoven which is independent of the filter substrate and which has the superabsorbent.

30. The air inlet or air outlet filter according to claim 21, in which the nonwoven fabric has a basis weight of less than 250 g/m2, preferably of less than 200 g/m2 and particularly preferably less than 180 g/m2.

31. The air inlet or air outlet filter according to claim 21, in which the absorber mat made of nonwoven fabric is arranged downstream of the pleated filter in the flow direction in the case of an air inlet filter and upstream of the pleated filter in the flow direction in the case of an air outlet filter, wherein the absorber mat made of nonwoven fabric is arranged adjacent to the pleated filter or at a distance from the pleated filter.

32. A switch cabinet arrangement having a switch cabinet housing and at least one air inlet or air outlet filter according to claim 21, in which the filter housing is mounted in a vertical housing wall of the switch cabinet housing and has a lamella grid on an outer side of the switch cabinet housing.

33. The switch cabinet arrangement according to claim 32, in which the lamella grid has a plurality of vertically extending lamellae or consists of a plurality of lamellae extending vertically and parallel to one another.

34. The switch cabinet arrangement according to claim 32, in which the filter housing has a filter housing cover which has the lamella grid and can be pivoted with respect to a filter housing lower part fixed in the housing wall or can be removed therefrom and in which the pleated filter is held, wherein an absorber mat made of nonwoven fabric is held in the filter housing lower part.

35. The switch cabinet arrangement according to claim 32, in which the filter housing has a filter housing cover which has the lamella grid and can be pivoted with respect to a filter housing lower part or can be removed therefrom and in which the pleated filter and an absorber mat made of nonwoven fabric are held.

36. The switch cabinet arrangement according to claim 32, in which the pleated filter is arranged in the interior of the filter housing facing the lamella grid, wherein the lamella extends parallel to the pleats of the pleated filter, so that a vertically extending channel which is open towards the lamella grid is formed in each case between adjacent pleats of the pleated filter.

37. The switch cabinet arrangement according to claim 32, which has an air inlet filter and an air outlet filter, and wherein the air inlet filter is designed as a fan filter.
